(19) United States
(12) Patent Application Publication
(10) Pub. No.: US 2026/0215583 A1
(43) Pub. Date: Jul. 30, 2026

(54) SLIDE RAIL LOCK DEVICE

(71) Applicant: FOSITEK CORPORATION, New Taipei City (TW)

(72) Inventors: Chia-Hung SU, New Taipei City (TW); Chang-Yi Li, New Taipei City (TW)

(73) Assignee: FOSITEK CORPORATION, New Taipei City (TW)

(21) Appl. No.: 19/175,659

(22) Filed: Apr. 10, 2025

(30) Foreign Application Priority Data
Jan. 24, 2025 (TW) 114103611

(51) Int. Cl. A47B 88/473; A47B 88/483; H05K 5/02

(52) U.S. Cl. CPC A47B 88/473; A47B 88/483; H05K 5/0217

(57) ABSTRACT

A slide rail lock device includes a base unit, an engagement member, a drive member, and a lock member, and is adapted to be disposed on a slide rail that includes an outer rail and an inner rail. The base unit includes a base, an outer frame, and an inner support frame that cooperates with the base to define a movement slot. The outer frame has an eave portion, an outer connection portion, and an engagement portion. The engagement member separably engages the engagement portion. One end part of the eave portion that is distal to the outer connection portion is formed with a lock groove. The lock member is operable to engage the lock groove. The drive member is operable to move in the movement slot to urge the engagement member to rotate so that the engagement member is disengaged from the engagement portion of the outer frame.

### CROSS-REFERENCE TO RELATED APPLICATION

This application claims priority to Taiwanese Invention Patent Application No. 114103611, filed on January 24, 2025, the entire disclosure of which is incorporated by reference herein.

### FIELD

The present disclosure relates to a lock device, and more particularly to a slide rail lock device.

### BACKGROUND

A conventional slide rail lock device is adapted to be mounted to a slide rail unit. The slide rail unit is disposed on a server rack cabinet, and includes an outer rail that is fixedly connected to the server rack cabinet, and an inner rail that is slidable relative to the outer rail and that is connected to a server. The slide rail lock device is disposed between the inner rail and the outer rail, and is used for preventing the inner rail from sliding out of the outer rail. The slide rail lock device includes an outer connecting frame that is fixedly connected to the outer rail, and a locking member that is pivotably connected to the inner rail and that separably engages the outer connecting frame. When the locking member engages the outer connecting frame, the inner rail is prevented from sliding out of the outer rail. When the locking member is disengaged from the outer connecting frame, the inner rail is movable relative to the outer rail and thus the server may be removed from the server rack cabinet for maintenance. However, when a maintenance worker wants to maintain the server without removing the server from the server rack cabinet, the server cannot be positioned at a particular position because the inner rail and the server that is connected to the inner rail are always movable relative to the outer rail as long as the locking member of the conventional slide rail lock device is disengaged from the outer connecting frame. In that situation, the maintenance of the server becomes more difficult and inconvenient, so there is still room for improvement.

### SUMMARY

Therefore, an object of the disclosure is to provide a slide rail lock device that can alleviate at least one of the drawbacks of the prior art.

According to the disclosure, the slide rail lock device is adapted to be disposed on a slide rail that includes an outer rail and an inner rail which is movable relative to the outer rail. The slide rail lock device includes a base unit and a lock unit. The base unit includes an outer frame that is adapted to be fixedly connected to the outer rail, a base that is adapted to be fixedly connected to the inner rail, and an inner support frame that is fixedly connected to the base. The outer frame has an outer connection portion that is adapted to be fixedly connected to the outer rail, an engagement portion that extends from the outer connection portion in a direction away from the outer rail, and an eave portion that is connected to the outer connection portion and an upper edge of the engagement portion. One end part of the eave portion that is distal to the outer connection portion is formed with a lock groove. The inner support frame and the base cooperatively define a movement slot. The lock unit includes an engagement member that is rotatably disposed on the base unit, a drive member that is connected to the engagement member and that is movably disposed in the movement slot, a lock member that is rotatably disposed on the base unit, and a lock resilient member that is disposed on the inner support frame and that abuts against the lock member. The engagement member has an engagement section that separably engages the engagement portion of the outer frame. The lock member has a lock section that is operable to engage the lock groove. The drive member is operable to move in the movement slot to urge the engagement member to rotate so that the engagement section of the engagement member is disengaged from the engagement portion of the outer frame, thereby allowing the inner rail, the base, and the inner support frame to move relative to the outer rail. The lock resilient member resiliently biases the lock member upwardly when the inner rail, the base and the inner support frame are moved relative to the outer rail to a position in which the lock section of the lock member is located below the lock groove so that the lock section of the lock member is operable to engage the lock groove.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a fragmentary perspective view illustrating that an embodiment of a slide rail lock device according to the present disclosure is disposed on a slide rail.

FIG. 2 is a fragmentary, partly exploded perspective view of an assembly of the embodiment and the slide rail.

FIG. 3 is an exploded perspective view of the embodiment.

FIG. 4 is an exploded perspective view of the embodiment taken from another angle.

FIG. 5 is a rear view of an inner support frame of a base unit of the embodiment.

FIG. 6 is a fragmentary rear view of the assembly, illustrating an engagement section of an engagement member of a lock unit of the embodiment engaging an engagement segment of an engagement portion of an outer frame of the embodiment, and illustrating a switch member of the lock unit in an initial position.

FIG. 7 is a fragmentary rear view of the assembly, illustrating that the engagement member is urged by a drive member of the embodiment to rotate such that the engagement section of the engagement member is moved downwardly and disengaged from the engagement segment of the engagement portion of the outer frame.

FIG. 8 is a fragmentary rear view of the assembly, illustrating the switch member in a lock position.

FIG. 9 is a fragmentary rear view of the assembly, illustrating a lock section of a lock member of the embodiment engaging a lock groove of the outer frame.

### DETAILED DESCRIPTION

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

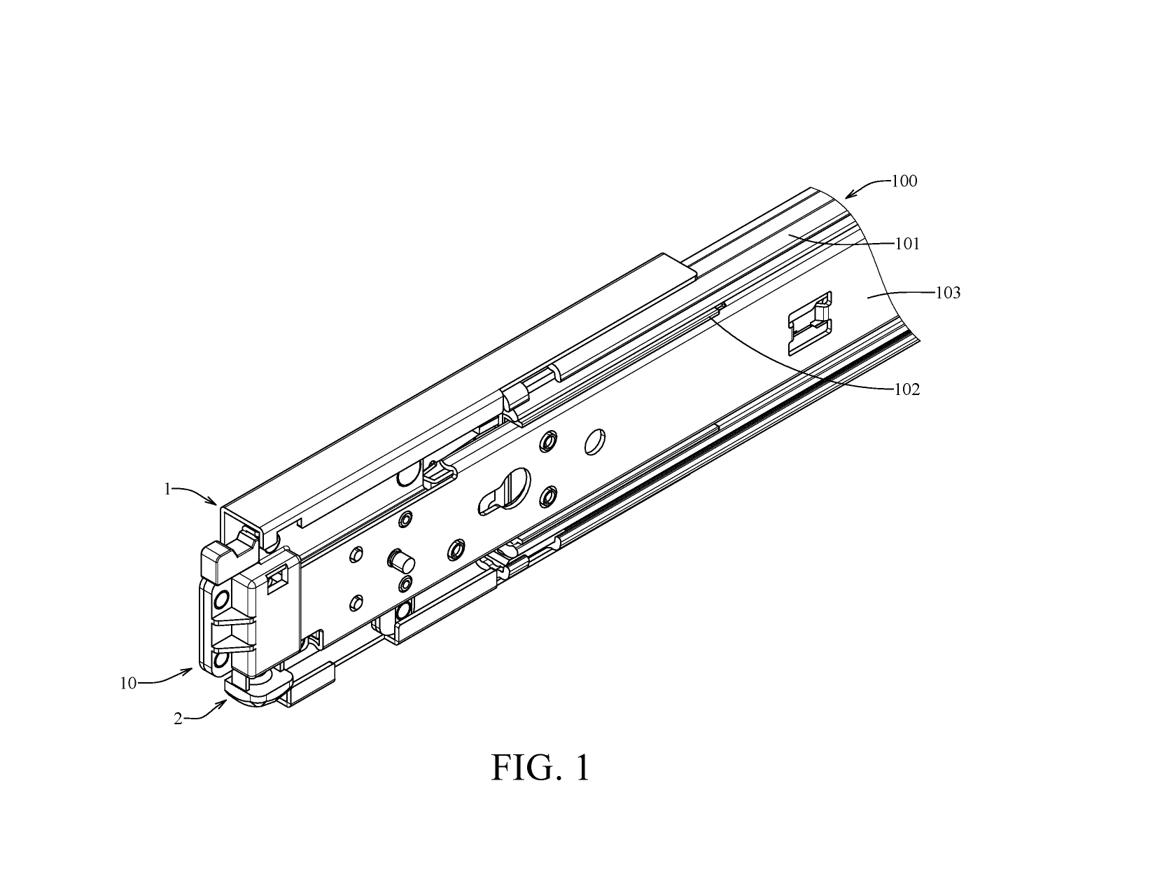

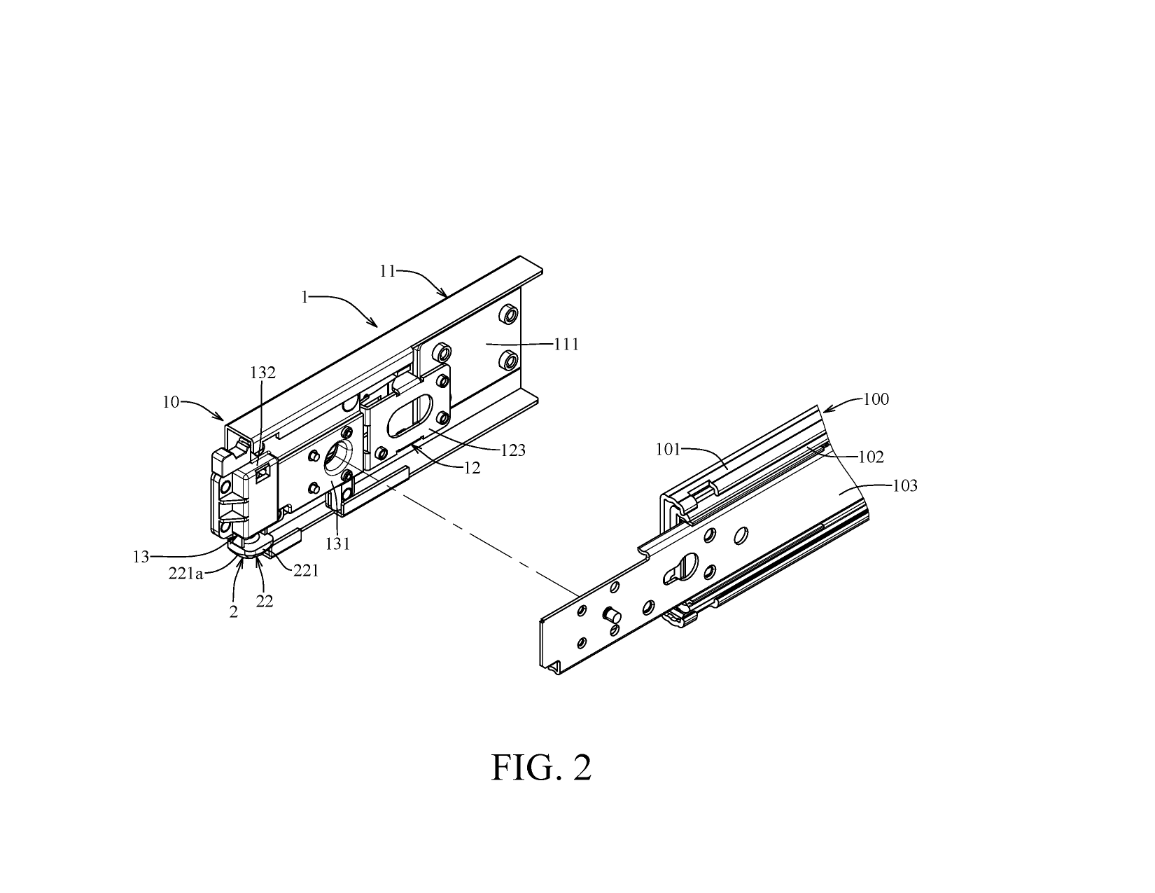

Referring to FIGS. 1 and 2, an embodiment of a slide rail lock device 10 according to the present disclosure is adapted to be disposed on a slide rail 100. The slide rail 100 is disposed on a server rack cabinet (not shown), and includes an outer rail 101, a middle rail 102 that is movably disposed on the outer rail 101, and an inner rail 103 that is movably disposed on the middle rail 102 and that is movable relative to the outer rail 101 and the middle rail 102. The outer rail 101 is fixedly connected to the server rack cabinet (not shown). The inner rail 103 is fixedly connected to a server (not shown). The slide rail lock device 10 includes a base unit 1 and a lock unit.

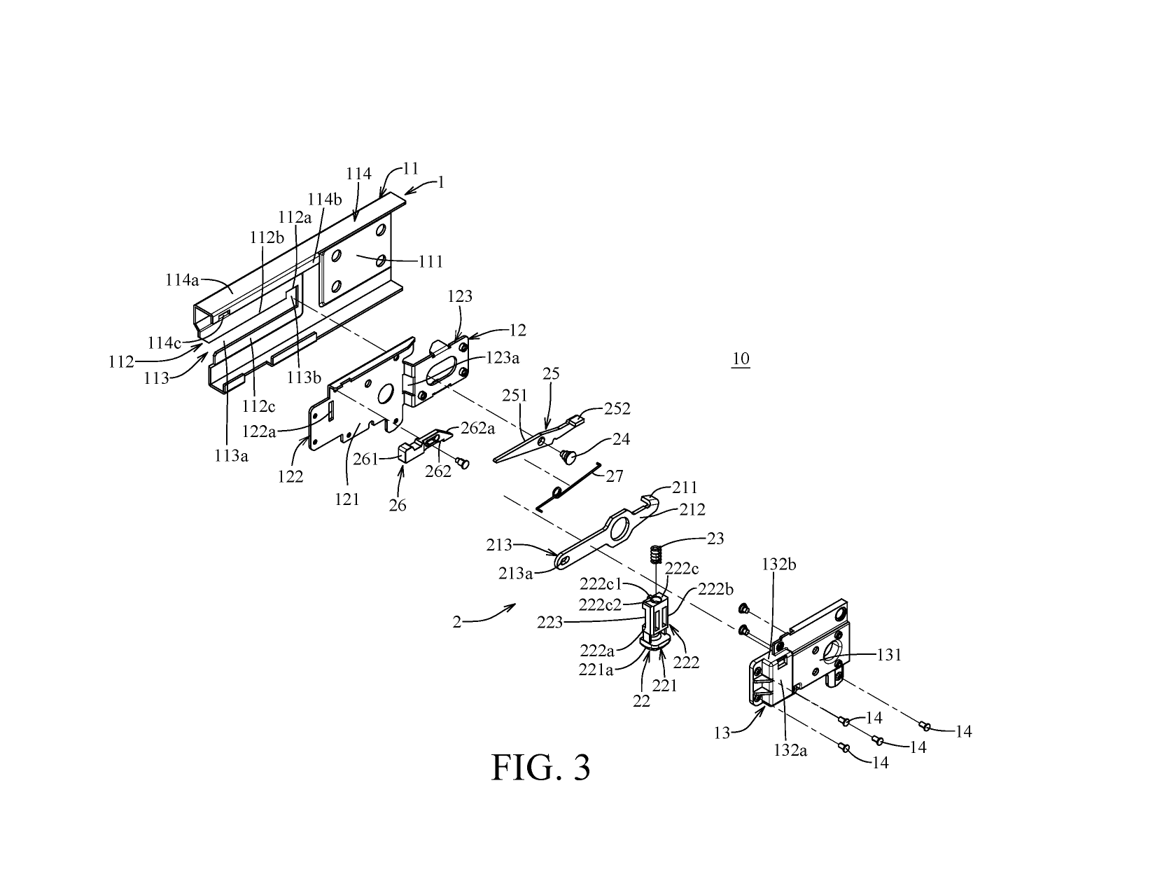

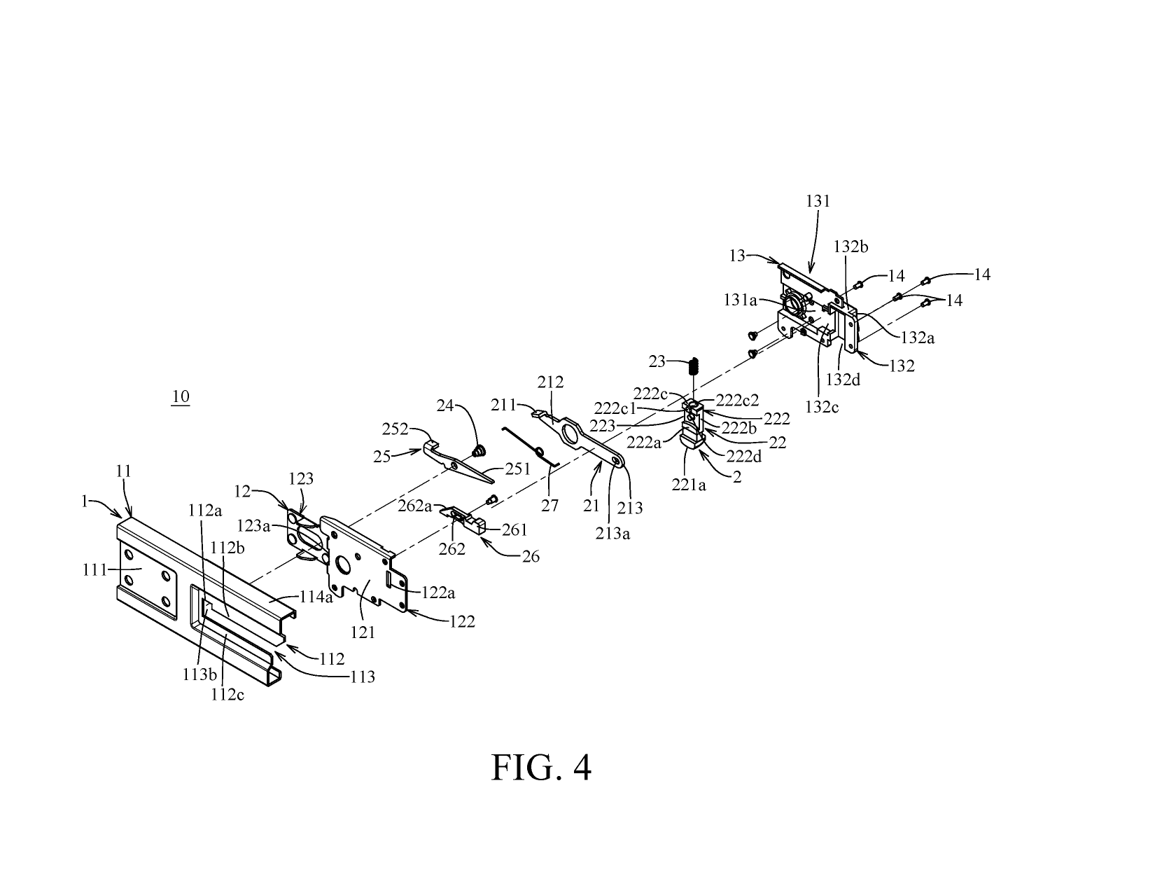

Referring to FIGS. 2 to 4, the base unit 1 includes an outer frame 11 that is adapted to be fixedly connected to the outer rail 101, a base 12 that is adapted to be fixedly connected to the inner rail 103, and an inner support frame 13 that is fixedly connected to the base 12 and that cooperates with the base 12 to define a movement slot 132d. The outer frame 11 has an outer connection portion 111 that is adapted to be fixedly connected to the outer rail 101, an engagement portion 112 that extends from the outer connection portion 111 in a direction away from the outer rail 101, and an eave portion 114 that is connected to the outer connection portion 111 and an upper edge of the engagement portion 112. The engagement portion 112 has an upper plate segment 112a that is connected to the outer connection portion 111, an engagement segment 112b that extends downwardly from the upper plate segment 112a and that is spaced apart from the outer connection portion 111, and a lower plate segment 112c that is connected to the outer connection portion 111 and that is spaced apart from and located below the upper plate segment 112a. The upper plate segment 112a cooperates with the engagement segment 112b and the lower plate segment 112c to define a plate slot 113. The plate slot 113 has a first slot segment 113a that is defined by the engagement segment 112b and the lower plate segment 112c, and a second slot segment 113b that is defined by the upper plate segment 112a and the lower plate segment 112c. The first slot segment 113a is in spatial communication with the second slot segment 113b, and a width of the first slot segment 113a in an up-down direction is smaller than a width of the second slot segment 113b in the up-down direction. The eave portion 114 has a top plate segment 114a that is connected to the outer connection portion 111 and the upper edge of the engagement portion 112, and a side plate segment 114b that extends downwardly from the top plate segment 114a and that is spaced apart from the outer connection portion 111 and the engagement portion 112. One end part of the side plate segment 114b that is distal to the outer connection portion 111 is formed with a lock groove 114c.

The base 12 has a base plate portion 121 that is rotatably connected to the lock unit 2, a guide portion 122 that is connected to one side of the base plate portion 121 which is distal to the outer rail 101, and an inner connection portion 123 that is connected to another side of the base plate portion 121 which is proximate to the outer rail 101. A surface of the guide portion 122 that faces the inner support frame 13 is formed with a guide groove 122a that extends in the up-down direction. The inner connection portion 123 is adapted to be fixedly connected to the inner rail 103, and is formed with a plate opening 123a.

Referring to FIGS. 2 to 5, the inner support frame 13 includes a cover portion 131 that is connected to the base plate portion 121, and a movement portion 132 that is connected to the cover portion 131. The cover portion 131 is connected to the base plate portion 121 by, but not limited by, four fastening members 14. The cover portion 131 is formed with an accommodation groove 131a. The movement portion 132 includes a base wall 132a and a surrounding wall 132b that extends from the base wall 132a toward the guide portion 122 of the base 12. The surrounding wall 132b is formed with a communication opening 132c that is in spatial communication with the accommodation groove 131a. The base wall 132a cooperates with the surrounding wall 132b and the guide portion 122 of the base 12 to define the movement slot 132d that opens downwardly.

The lock unit 2 includes an engagement member 21 that is rotatably disposed on the base plate portion 121 of the base 12, a drive member 22 that is connected to the engagement member 21 and that is movably disposed in the movement slot 132d, a drive resilient member 23 that is disposed between the inner support frame 13 and the drive member 22, a lock member 25 that is rotatably disposed on the base unit 1, a switch member 26 that is movably disposed on the base 12 and that is located below the eave portion 114 of the outer frame 11, and a lock resilient member 27 that is disposed on the inner support frame 13 and that abuts against the lock member 25. The drive resilient member 23 is configured to be a spring. One end of the drive resilient member 23 abuts against the surrounding wall 132b of the movement portion 132 of the inner support frame 13, and another end of the drive resilient member 23 abuts against the drive member 22. The accommodation groove 131a of the cover portion 131 of the inner support frame 13 accommodates the engagement member 21. The engagement member 21 has an engagement section 211 that separably engages the engagement segment 112b of the engagement portion 112 of the outer frame 11 and that is movably disposed in the second slot segment 113b of the plate slot 113, a rotation section 212 that is rotatably disposed on the base 12 and that is connected to the engagement section 211, and a linkage section 213 that is connected to the rotation section 212 and that extends through the communication opening 132c of the surrounding wall 132b to be connected to the drive member 22. The rotation section 212 extends through the plate opening 123a of the inner connection portion 123 of the base 12 so that the engagement section 211 of the engagement member 21 is able to engage the engagement portion 112 of the outer frame 11. The linkage section 213 is formed with an elongated linkage slot 213a.

The drive member 22 is substantially in a shape of a square column, and has an operation section 221 and a drive section 222 that is connected to the operation section 221. The operation section 221 is formed with an operation surface 221a that protrudes downwardly and that is arc-shaped. In one embodiment, the operation surface 221a is hemispherical. The drive section 222 has a bottom wall 222a that is connected to the operation section 221, a side wall 222b that extends from the bottom wall 222a in a direction away from the operation section 221, and a top wall 222c that is connected to the side wall 222b and that is spaced apart from the bottom wall 222a. The drive section 222 defines a receive groove 223 that receives the linkage section 213 of the engagement member 21. The side wall 222b is formed with a linkage protrusion 222d that is movably disposed in the linkage slot 213a. A surface of the top wall 222c of the drive section 222 of the drive member 22 that faces the base 12 is formed with a guide block 222c1 that extends in the up-down direction and into the guide groove 122a (i.e., the surface of the guide portion 122 of the base 12 that faces the inner support frame 13 also faces the drive member 22). An upper surface of the top wall 222c of the drive section 222 of the drive member 22 is formed with a top recess 222c2 that at least partially accommodates the drive resilient member 23.

The lock member 25 is substantially in a shape of an elongated rod, and has a body section 251 that is rotatably connected to the base 12, and a lock section 252 that is connected to one end of the body section 251 which is distal to the switch member 26. The body section 251 is rotatably connected to the base plate portion 121 of the base 12 by a rotation connecting member 24. The switch member 26 has a switch section 261 that projects out of the eave portion 114 of the outer frame 11, and a movement section 262 that is connected to the switch section 261. The movement section 262 has an inclined surface 262a that faces the eave portion 114 of the outer frame 11 and that is operable to block the body section 251 of the lock member 25. The switch member 26 is movable between an initial position and a lock position. When the switch member 26 is in the initial position, the switch member 26 blocks the body section 251 of the lock member 25. When the switch member 26 is in the lock position, the switch member 26 is moved away from the lock member 25.

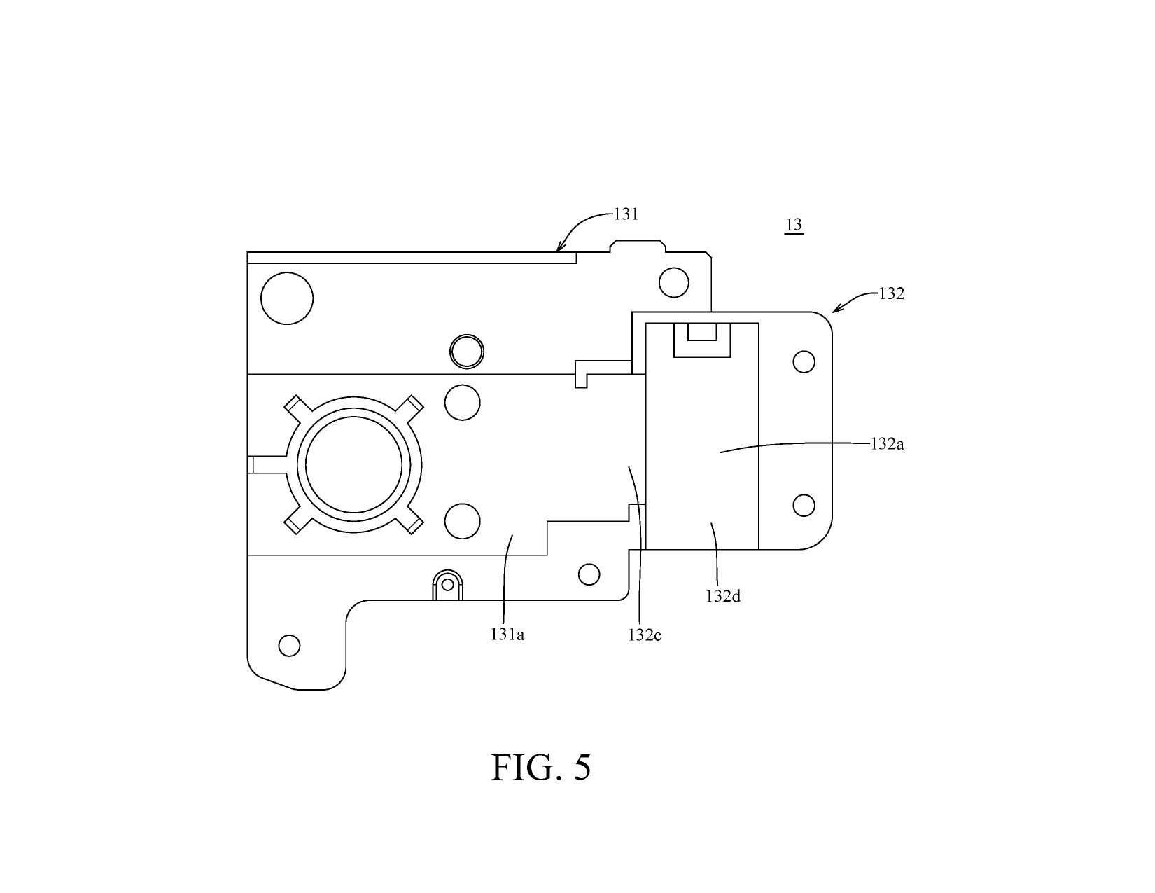

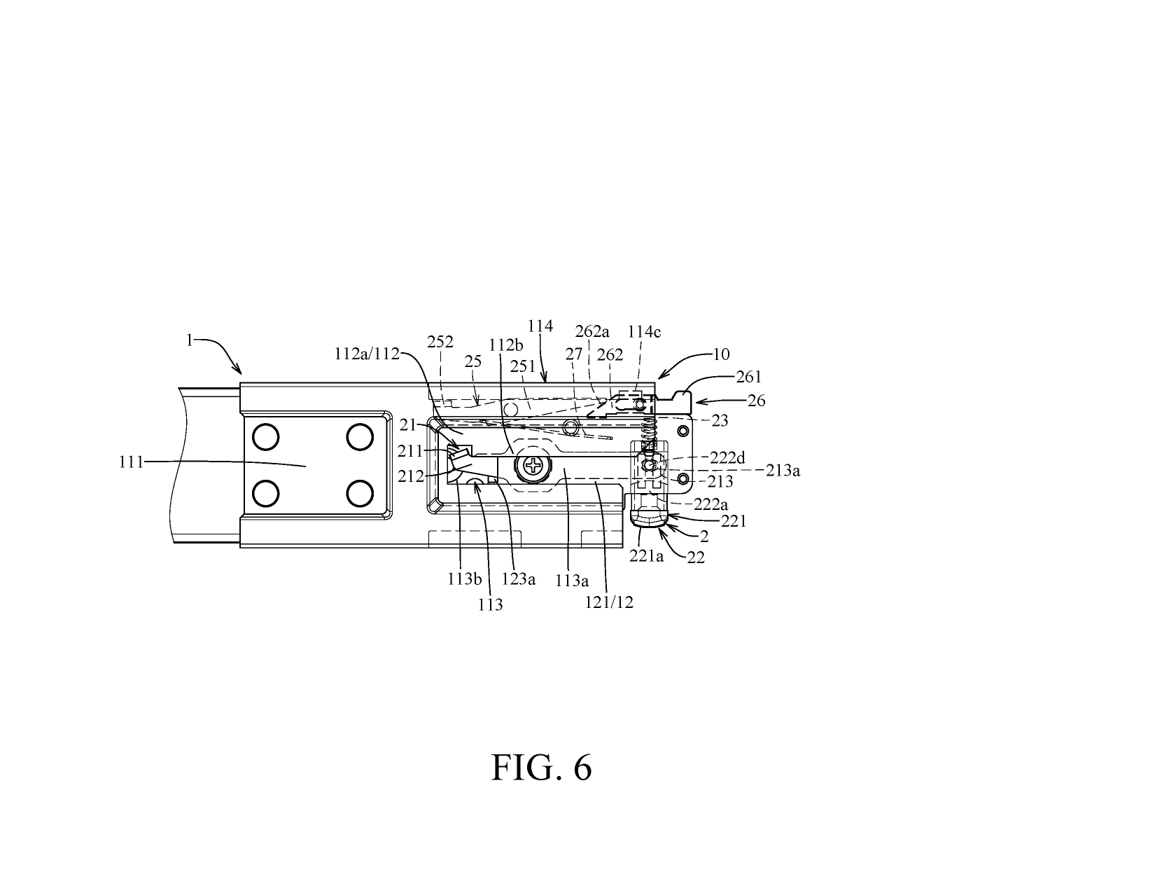

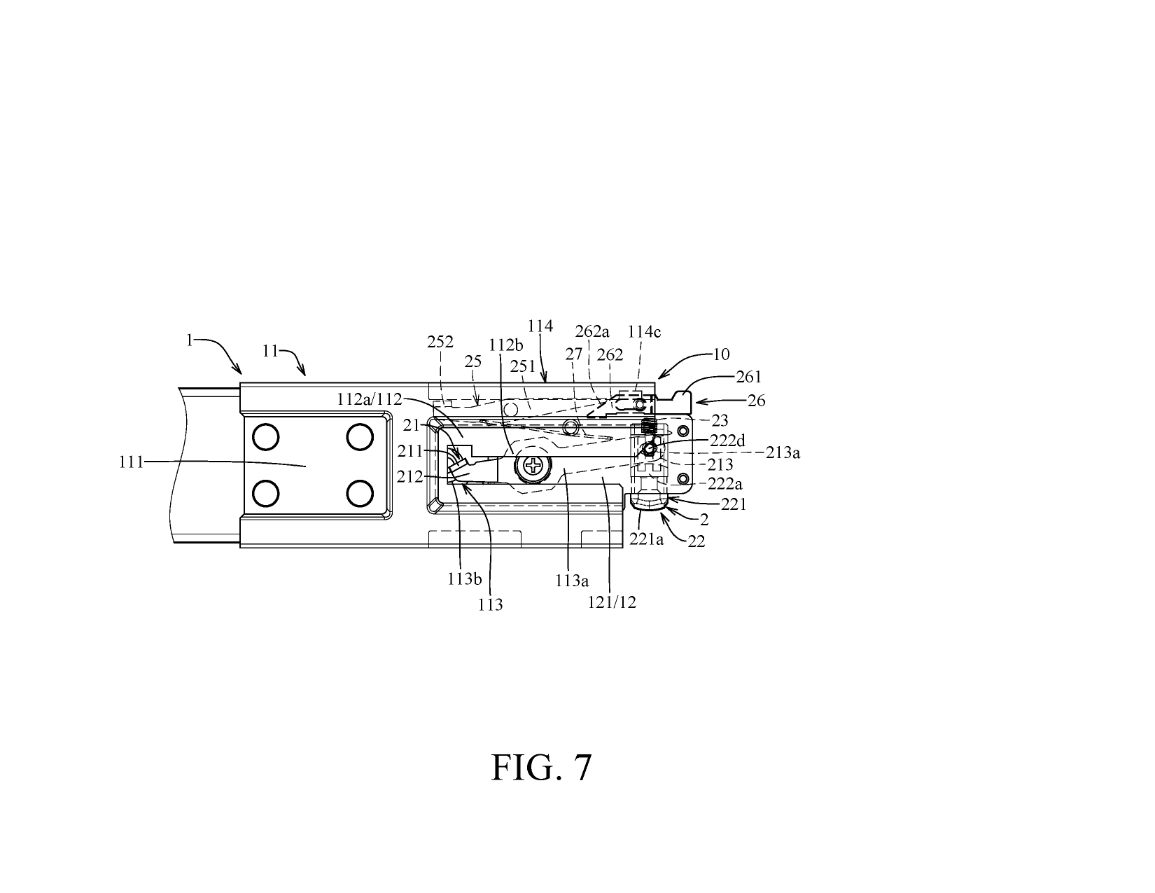

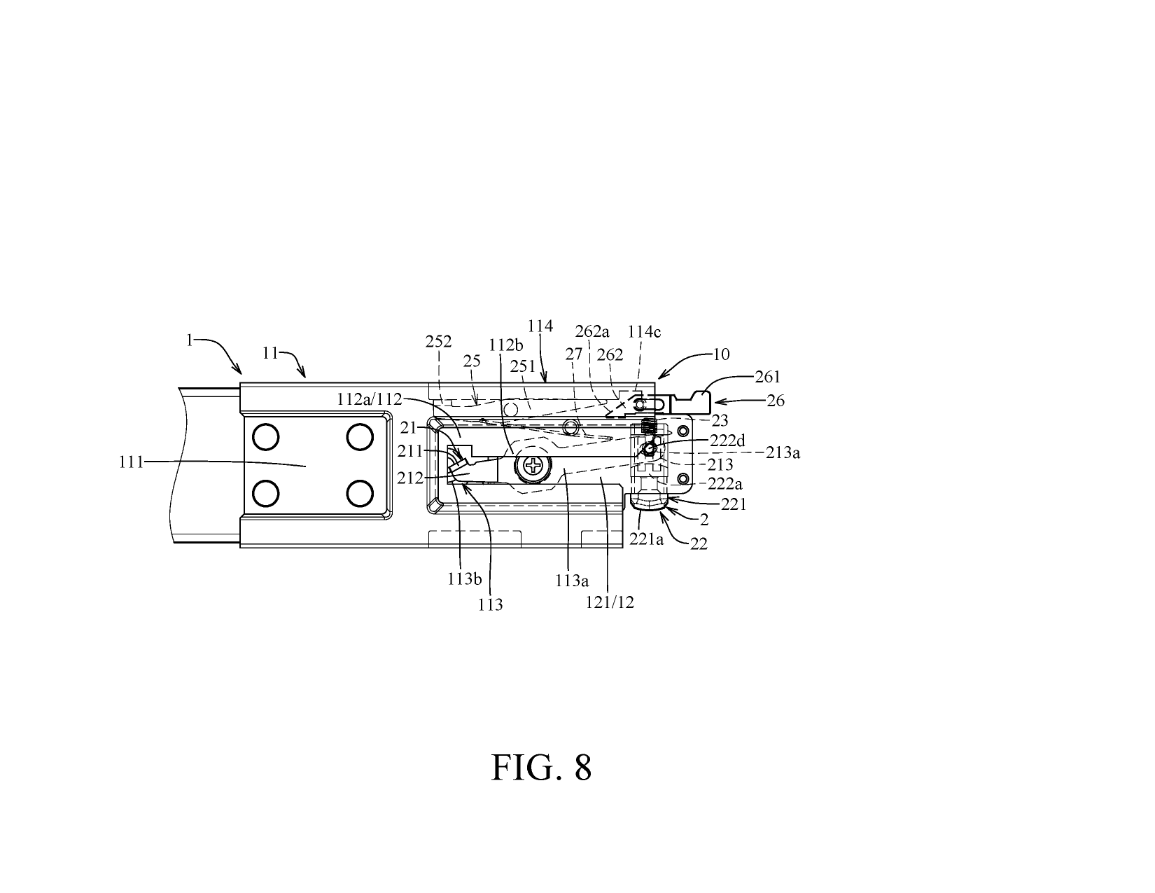

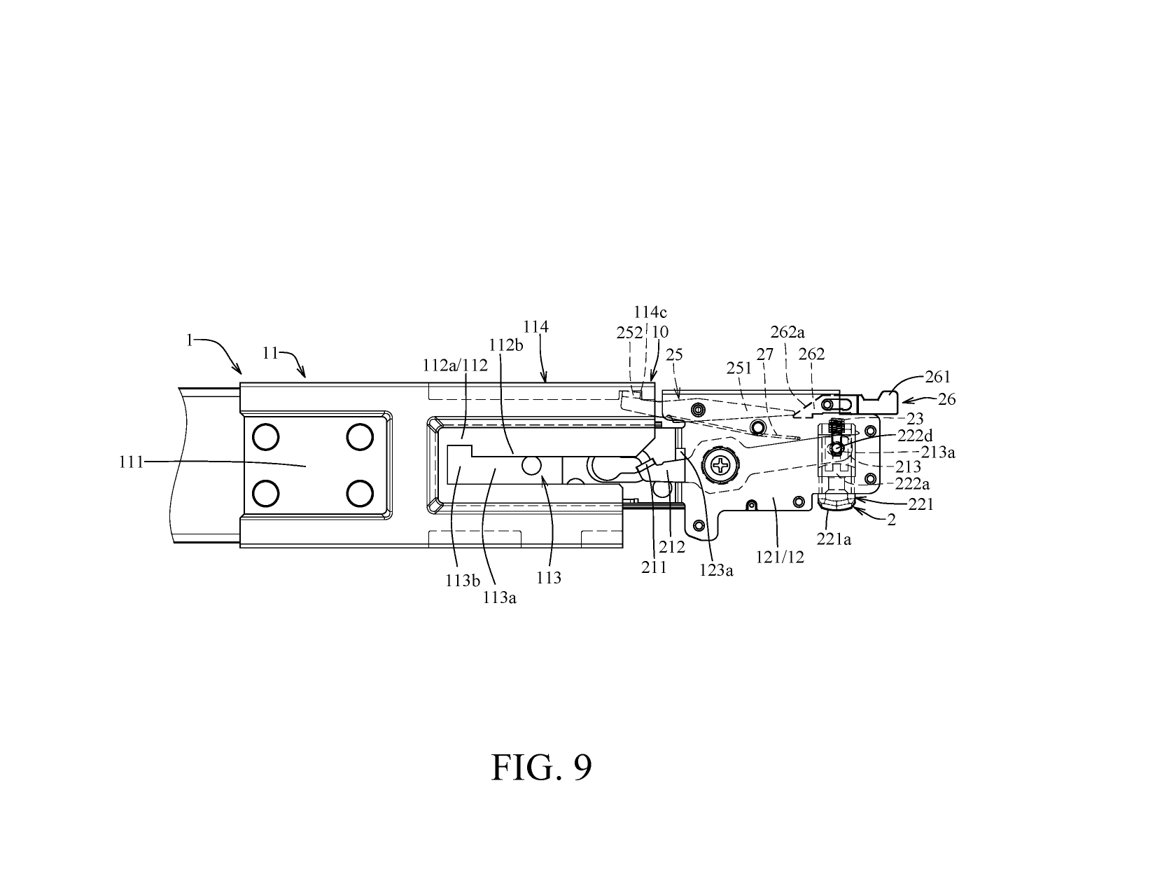

Referring to FIGS. 1 and 6 to 9, an operating process of a slide rail lock device 10 is described below. As shown in FIG. 6, when the drive member 22 is not operated, the engagement section 211 of the engagement member 21 engages the engagement segment 112b of the engagement portion 112 of the outer frame 11 so that the inner rail 103 is prevented from sliding out of the outer rail 101. Next, when an external object (not shown) is moved toward the drive member 22 in a longitudinal direction of the slide rail 100 and abuts against the operation surface 221a, because the operation surface 221a protrudes downwardly and is hemispherical, the external object pushes the drive member 22 upwardly as the external object keeps moving in the longitudinal direction of the slide rail 100. Thus, the drive member 22 is operable to move upwardly in the movement slot 132d (see FIG. 5). By virtue of the linkage protrusion 222d of the drive section 222 of the drive member 22 being movably disposed in the linkage slot 213a, the linkage protrusion 222d urges the linkage section 213 of the engagement member 21 to move upwardly when the drive member 22 moves upwardly in the movement slot 132d, thereby urging the engagement member 21 to rotate counterclockwise (viewing from FIGS. 6 to 7). Consequently, the engagement section 211 of the engagement member 21 moves downwardly in the second slot segment 113b to a position as shown in FIG. 7 such that the engagement section 211 is disengaged from the engagement segment 112b of the engagement portion 112 of the outer frame 11. The inner ail 103, the base 12, and the inner support frame 13 (see FIG. 5) are allowed to move relative to the outer rail 101 after the engagement section 211 is disengaged from the engagement segment 112b of the engagement portion 112. When the engagement section 211 is disengaged from the engagement segment 112b of the engagement portion 112 of the outer frame 11, and when the inner rail 103, the base 12 and the inner support frame 13 are moved relative to the outer rail 101, the engagement section 211 moves past the first slot segment 113a of the plate slot 113 and is separated from the outer frame 11. At this time, when the switch member 26 is in the initial position, the inclined surface 262a blocks the body section 251 of the lock member 25 so that the lock member 25 is prevented from rotating, and that the lock section 252 of the lock member 25 is not allowed to engage the lock groove 114c of the eave portion 114 of the outer frame 11 when the inner rail 103, the base 12, and the inner support frame 13 are moved relative to the outer rail 101 to a position in which the lock section 252 of the lock member 25 is located below the lock groove 114c. Therefore, the server (not shown) that is fixedly connected to the inner rail 103 may be removed from the server rack cabinet (not shown) for maintenance. When a maintenance worker wants to maintain the server without removing the server from the server rack cabinet, the maintenance worker may operate the switch member 26 so as to urge the switch member 26 to move to the lock position (i.e., away from the lock member 25) as shown in FIG. 8. When the switch member 26 is in the lock position and when the inner rail 103, the base 12, and the inner support frame 13 are moved relative to the outer rail 101 to the position in which the lock section 252 of the lock member 25 is located below the lock groove 114c, the body section 251 is not blocked by the inclined surface 262a of the switch member 26 so that the lock member 25 is allowed to rotate, and that the lock resilient member 27 resiliently biases the lock member 25 upwardly to urge the lock section 252 of the lock member 25 to engage the lock groove 114c as shown in FIG. 9 (i.e., the lock section 252 of the lock member 25 is able to engage the lock groove 114c by operation of the switch member 26). At this time, the inner rail 103 and the server are only pulled out a certain distance (i.e., not completely) relative to the outer rail 101, and the base 12, the inner support frame 13, the engagement member 21, the inner rail 103, and the server are ensured to be positioned at a particular position (i.e., not movable relative to the outer frame 11). Therefore, the maintenance worker may maintain the server without removing the server from the server rack cabinet, and the maintenance of the server becomes more convenient. It should be noted that, through configurations in which the drive member 22 urges the linkage section 213 of the engagement member 21 to move upwardly via movement of the linkage protrusion 222d of the drive section 222 of the drive member 22 in the linkage slot 213a, fit tolerance between the engagement member 21 and the drive member 22 is increased. Even if engagement members that are mass-produced are of unequal size, by virtue of the linkage protrusion 222d being movably disposed in the elongated linkage slot 213a, the drive member 22 may still urge the linkage section 213 to move upwardly, thereby urging any one of the unequally-sized engagement members to rotate.

In summary, by virtue of the lock section 252 of the lock member 25 of the slide rail lock device 10 being operable to engage the lock groove 114c, the inner rail 103 may be pulled out for only a certain distance while positioned relative to the outer frame 11, thereby facilitating the maintenance of the server that is fixedly connected to the inner rail 103. Therefore, the purpose of the present disclosure is indeed achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A slide rail lock device adapted to be disposed on a slide rail that includes an outer rail and an inner rail which is movable relative to the outer rail, the slide rail lock device comprising:
a base unit including an outer frame that is adapted to be fixedly connected to the outer rail, a base that is adapted to be fixedly connected to the inner rail, and an inner support frame that is fixedly connected to the base, the outer frame having an outer connection portion that is adapted to be fixedly connected to the outer rail, an engagement portion that extends from the outer connection portion in a direction away from the outer rail, and an eave portion that is connected to the outer connection portion and an upper edge of the engagement portion, one end part of the eave portion that is distal to the outer connection portion being formed with a lock groove, the inner support frame and the base cooperatively defining a movement slot; and
a lock unit including an engagement member that is rotatably disposed on the base unit, a drive member that is connected to the engagement member and that is movably disposed in the movement slot, a lock member that is rotatably disposed on the base unit, and a lock resilient member that is disposed on the inner support frame and that abuts against the lock member, the engagement member having an engagement section that separably engages the engagement portion of the outer frame, the lock member having a lock section that is operable to engage the lock groove, the drive member being operable to move in the movement slot to urge the engagement member to rotate so that the engagement section of the engagement member is disengaged from the engagement portion of the outer frame, thereby allowing the inner rail, the base, and the inner support frame to move relative to the outer rail, the lock resilient member resiliently biasing the lock member upwardly when the inner rail, the base and the inner support frame are moved relative to the outer rail to a position in which the lock section of the lock member is located below the lock groove so that the lock section of the lock member is operable to engage the lock groove.

2. The slide rail lock device as claimed in claim 1, wherein the engagement member further has a rotation section that is rotatably disposed on the base and that is connected to the engagement section, and a linkage section that is connected to the rotation section and the drive member.

3. The slide rail lock device as claimed in claim 2, wherein the drive member has an operation section and a drive section that is connected to the operation section, the drive section having a bottom wall that is connected to the operation section, a side wall that extends from the bottom wall in a direction away from the operation section, and a top wall that is connected to the side wall and that is spaced apart from the bottom wall, the drive section defining a receive groove that receives the linkage section of the engagement member.

4. The slide rail lock device as claimed in claim 3, wherein the linkage section of the engagement member is formed with an elongated linkage slot, and the side wall of the drive member is formed with a linkage protrusion that is movably disposed in the linkage slot.

5. The slide rail lock device as claimed in claim 3, wherein the base has a base plate portion that is rotatably connected to the engagement member, a guide portion that is connected to one side of the base plate portion which is distal to the outer rail, and an inner connection portion that is connected to another side of the base plate portion which is proximate to the outer rail, the inner connection portion being formed with a plate opening through which the engagement member extends so that the engagement section of the engagement member is able to engage the engagement portion of the outer frame, the guide portion and the inner support frame cooperatively defining the movement slot, the inner connection portion of the base being adapted to be fixedly connected to the inner rail.

6. The slide rail lock device as claimed in claim 5, wherein the inner support frame includes a cover portion that is connected to the base plate portion, and a movement portion that is connected to the cover portion, the cover portion being formed with an accommodation groove that accommodates the engagement member, the movement portion including a base wall and a surrounding wall that extends from the base wall toward the guide portion of the base, the surrounding wall being formed with a communication opening that is in spatial communication with the accommodation groove, the linkage section of the engagement member extending through the communication opening, the base wall cooperating with the surrounding wall and the guide portion of the base to define the movement slot that opens downwardly.

7. The slide rail lock device as claimed in claim 6, wherein a surface of the guide portion of the base that faces the drive member is formed with a guide groove that extends in an up-down direction, and the top wall of the drive section of the drive member is formed with a guide block that extends in the up-down direction and into the guide groove.

8. The slide rail lock device as claimed in claim 6, wherein the lock unit further includes a drive resilient member that is configured to be a spring, an upper surface of the top wall of the drive section of the drive member being formed with a top recess that at least partially accommodates the drive resilient member, one end of the drive resilient member abutting against the surrounding wall of the movement portion of the inner support frame.

9. The slide rail lock device as claimed in claim 1, wherein the lock member further has a body section that is rotatably connected to the base, the lock unit further including a switch member that is movably disposed on the base and that is located below the eave portion of the outer frame, the lock section of the lock member being connected to one end of the body section that is distal to the switch member, the switch member being movable between an initial position and a lock position, the switch member blocking the body section of the lock member when the switch member is in the initial position so that the lock section of the lock member is not allowed to engage the lock groove of the eave portion when the inner rail, the base and the inner support frame are moved relative to the outer rail to the position in which the lock section of the lock member is located below the lock groove, the switch member being moved away from the lock member when the switch member is in the lock position so that the lock section of the lock member engages the lock groove when the inner rail, the base and the inner support frame are moved relative to the outer rail to the position in which the lock section of the lock member is located below the lock groove.

10. The slide rail lock device as claimed in claim 9, wherein the switch member has a switch section that projects out of the eave portion of the outer frame, and a movement section that is connected to the switch section, the movement section having an inclined surface that faces the eave portion of the outer frame and that is operable to block the body section of the lock member, the inclined surface blocking the body section when the switch member is in the initial position so that the lock member is prevented from rotating.

11. The slide rail lock device as claimed in claim 1, wherein the eave portion of the outer frame has a top plate segment that is connected to the outer connection portion of the outer frame and the upper edge of the engagement portion of the outer frame, and a side plate segment that extends downwardly from the top plate segment and that is spaced apart from the outer connection portion and the engagement portion, the lock groove being formed at the side plate segment.
